(19) United States
(12) Patent Application Publication
(10) Pub. No.: US 2025/0038773 A1
(43) Pub. Date: Jan. 30, 2025

(54) RADIO FREQUENCY MODULE AND COMMUNICATION DEVICE

(71) Applicant: Murata Manufacturing Co., Ltd., Nagaokakyo-shi (JP)

(72) Inventors: Hiroyuki KANI, Nagaokakyo-shi (JP); Yoshihiro YOSHIMURA, Nagaokakyo-shi (JP); Kiyoshi AIKAWA, Nagaokakyo-shi (JP); Takahiro YAMASHITA, Nagaokakyo-shi (JP); Yuusuke SUZUKI, Nagaokakyo-shi (JP); Hidetaka TAKAHASHI, Nagaokakyo-shi (JP); Takanori ITO, Nagaokakyo-shi (JP); Takuma KUROYANAGI, Nagaokakyo-shi (JP)

(73) Assignee: Murata Manufacturing Co., Ltd., Nagaokakyo-shi (JP)

(21) Appl. No.: 18/910,105

(22) Filed: Oct. 9, 2024

Related U.S. Application Data
(63) Continuation of application No. PCT/JP2023/014387, filed on Apr. 7, 2023.

(30) Foreign Application Priority Data
Apr. 12, 2022 (JP) 2022-065868

(51) Int. Cl. H04B 1/00; H03H 9/64; H04B 1/16

(52) U.S. Cl. CPC H04B 1/006; H03H 9/6406; H04B 1/1607

(57) ABSTRACT

A radio frequency module includes a mounting board, a first acoustic wave filter including a first support disposed at a first main surface of the mounting board, a second acoustic wave filter including a second support disposed on the first acoustic wave filter, and a shield electrode. The shield electrode covers at least a part of the resin layer. The first acoustic wave filter and the second acoustic wave filter pass signals to perform simultaneous communication. A main surface of the second acoustic wave filter on an opposite side from a first acoustic wave filter side is in contact with the shield electrode. A ground electrode of the mounting board is connected to a functional electrode of the first acoustic wave filter.

### CROSS-REFERENCE TO RELATED APPLICATIONS

The present application is a continuation application of PCT International Application No. PCT/JP2023/014387 filed on Apr. 7, 2023, designating the United States of America, which is based on and claims priority to Japanese patent application JP 2022-065868, filed Apr. 12, 2022. The entire disclosures of the above-identified applications, including the specifications, the drawings, and the claims are incorporated herein by reference in their entirety.

### BACKGROUND

A structure may include a transmission filter (fifth filter) which is provided at a main surface of a mounting board, and another transmission filter (sixth filter) which is stacked on the above transmission filter.

### SUMMARY

According to an aspect of the present disclosure, a radio frequency module includes a mounting board, a first acoustic wave filter, a second acoustic wave filter, a first resin layer, and a first shield electrode. The mounting board has a first main surface and includes a first ground electrode. The first acoustic wave filter is disposed at the first main surface of the mounting board. The second acoustic wave filter is disposed on the first acoustic wave filter. The first resin layer covers at least a part of the first acoustic wave filter and the second acoustic wave filter. The first shield electrode covers at least a part of the first resin layer. Both the first acoustic wave filter and the second acoustic wave filter are filters that support at least transmission. A first transmission signal passing through the first acoustic wave filter and a second transmission signal passing through the second acoustic wave filter are capable of simultaneous communication. A second main surface of the second acoustic wave filter on an opposite side from a first acoustic wave filter side is in contact with the first shield electrode. The first acoustic wave filter includes a first functional electrode. The first ground electrode of the mounting board is connected to the first functional electrode of the first acoustic wave filter.

The present disclosure generally relates to a radio frequency module and a communication device, and more particularly relates to a radio frequency module including a plurality of filters and a communication device including the radio frequency module.

According to an aspect of the present disclosure, a communication device includes the radio frequency module and a signal processing circuit. The signal processing circuit is connected to the radio frequency module.

### Advantageous Effects of Disclosure

With the radio frequency module and the communication device according to the aspects of the present disclosure, it is possible to improve heat dissipation properties of two transmission filters in a case of transmitting two transmission signals capable of simultaneous communication.

### BRIEF DESCRIPTION OF DRAWINGS

FIG. 1 is a plan view of a radio frequency module according to exemplary embodiment 1.

FIG. 2 is a cross-sectional view taken along line X1-X1 in FIG. 1, related to the radio frequency module.

FIG. 3 is a circuit configuration diagram of a communication device including the radio frequency module.

FIG. 4 is a cross-sectional view of a radio frequency module according to exemplary embodiment 2.

FIG. 5 is a cross-sectional view of a radio frequency module according to exemplary embodiment 3.

FIG. 6 is a cross-sectional view of a radio frequency module according to exemplary embodiment 4.

FIG. 7 is a circuit configuration diagram of a radio frequency module according to Exemplary embodiment 5.

### DESCRIPTION OF EXEMPLARY EMBODIMENTS

However, in the structure described in the Background, in a case where the simultaneous communication is performed by transmission signals passing through the two transmission filters, it is necessary to improve heat dissipation properties of the two transmission filters.

the present disclosure provides a radio frequency module and a communication device capable of improving heat dissipation properties of two transmission filters in a case of transmitting two transmission signals capable of simultaneous communication.

Hereinafter, radio frequency modules and communication devices according to exemplary embodiments 1 to 5 will be described with reference to the drawings. The drawings referred to in exemplary embodiments 1 to 5 as follows are all schematic drawings, and the ratios of the respective sizes and thicknesses of the constituent elements in the drawings do not necessarily reflect the actual dimensional ratios.

### Exemplary Embodiment 1

First, a configuration of a radio frequency module 1 according to exemplary embodiment 1 will be described with reference to the drawings.

### (1) Radio Frequency Module

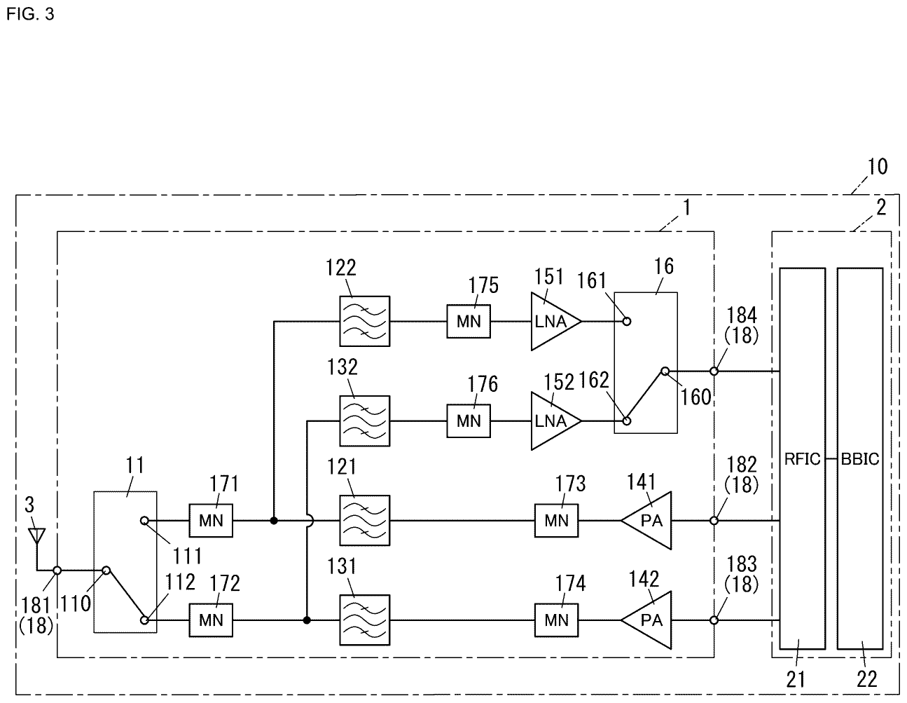

A radio frequency module 1 is used, for example, in a communication device 10 as shown in FIG. 3. For example, the communication device 10 is a mobile phone such as a smartphone. The communication device 10 is not limited to the mobile phone, and may be a wearable terminal such as a smart watch, for example. The radio frequency module 1 is, for example, a module capable of supporting the fourth generation mobile communication (4G) standard, the fifth generation mobile communication (5G) standard, and the like. For example, the 4G standard is the third generation partnership project (3GPP: registered trademark) long term evolution (LTE: registered trademark) standard. The 5G standard is, for example, the 5G new radio (NR).

The radio frequency module 1 is, for example, a module capable of supporting carrier aggregation and dual connectivity. Carrier aggregation and dual connectivity refer to a technology used for communication that uses radio waves in a plurality of frequency bands at the same time.

The communication device 10 performs communication in a plurality of communication bands. More specifically, the communication device 10 transmits a transmission signal in each of a plurality of communication bands and receives a reception signal in each of the plurality of communication bands. Specifically, the radio frequency module 1 receives a reception signal in a first communication band and a reception signal in a second communication band. In addition, the radio frequency module 1 transmits a transmission signal in the first communication band and a transmission signal in the second communication band.

The transmission signal and the reception signal in the first communication band are, for example, frequency division duplex (FDD) signals. In addition, the transmission signal and the reception signal in the second communication band are FDD signals. FDD is a communication technology that allocates different frequency regions to transmission and reception in radio communication and performs transmission and reception.

The first communication band is, for example, Band 1 of the 3GPP LTE standard. In addition, the second communication band is, for example, Band 3 of the 3GPP LTE standard. The power classes of Band 1 and Band 3 are being examined. The signal of the power class 2 has a signal strength higher than the signal of the power class 3. That is, the signal strength of the transmission signal in the second communication band is higher than the communication strength of the transmission signal in the first communication band.

### (2) Circuit Configuration of Radio Frequency Module

Next, a circuit configuration of the radio frequency module 1 according to exemplary embodiment 1 will be described with reference to FIG. 3.

As shown in FIG. 3, the radio frequency module 1 according to exemplary embodiment 1 includes a first transmission filter 121, a second transmission filter 131, a first reception filter 122, and a second reception filter 132. A first switch 11 and a second switch 16 are provided. In addition, the radio frequency module according to exemplary embodiment 1 further includes a power amplifier 141, a power amplifier 142, a low-noise amplifier 151, a low-noise amplifier 152, matching circuits 171 to 176, and a plurality of (four in the shown example) external connection terminals 18. The plurality of external connection terminals 18 include an antenna terminal 181, a first input terminal 182, a second input terminal 183, and an output terminal 184.

### (2.1) First Switch

As shown in FIG. 3, the first switch 11 is a switch for switching a path connected to the antenna terminal 181 from among the first transmission filter 121 and the first reception filter 122, and the second transmission filter 131 and the second reception filter 132. In other words, the first switch 11 is a switch for switching a path to be connected to the antenna terminal 181. The first switch 11 has a common terminal 110 and a plurality of (two in the shown example) selection terminals 111 and 112.

The common terminal 110 is connected to the antenna terminal 181. The selection terminal 111 is connected to the matching circuit 171. In addition, the selection terminal 112 is connected to the matching circuit 172.

The first switch 11 switches the connection between the common terminal 110, and the plurality of selection terminals 111 and 112. The first switch 11 is controlled by, for example, a signal processing circuit 2. The first switch 11 electrically connects the common terminal 110 to any one of the plurality of selection terminals 111 and 112 in accordance with a control signal from an RF signal processing circuit 21 of the signal processing circuit 2.

### (2.2) First Transmission Filter, Second Transmission Filter

The first transmission filter 121 and the second transmission filter 131 are filters that cause signals in frequency bands different from each other to pass therethrough. More specifically, the first transmission filter 121 is a filter that causes a transmission signal in the first communication band to pass through the first transmission filter 121. The second transmission filter 131 is a filter that causes a transmission signal of the second communication band to pass through the second transmission filter 131.

As will be described later, each of the first transmission filter 121 and the second transmission filter 131 is an acoustic wave filter having one or more acoustic wave resonators. In the present exemplary embodiment, the first transmission filter 121 is a first acoustic wave filter. In addition, in the present exemplary embodiment, the second transmission filter 131 is a second acoustic wave filter. As will be described later, the first transmission filter 121 and the second transmission filter 131 are included in a first electronic component 51 that is a single electronic component.

### (2.3) First Reception Filter, Second Reception Filter

The first reception filter 122 and the second reception filter 132 are filters that cause signals in frequency bands different from each other to pass therethrough. More specifically, the first reception filter 122 is a filter that causes a reception signal in the first communication band to pass through the first reception filter 122. The second reception filter 132 is a filter that causes a reception signal in the second communication band to pass through the second reception filter 132.

As will be described later, each of the first reception filter 122 and the second reception filter 132 is an acoustic wave filter having one or more acoustic wave resonators. The first reception filter 122 and the second reception filter 132 are included in a single electronic component as will be described later.

### (2.4) Power Amplifier

The power amplifier 141 is an amplifier that amplifies a transmission signal. More specifically, the power amplifier 141 amplifies a transmission signal in the first communication band. The power amplifier 141 is provided between the first transmission filter 121 and the first input terminal 182. The power amplifier 141 includes an input terminal and an output terminal. The input terminal of the power amplifier 141 is connected to an external circuit (for example, the signal processing circuit 2) with the first input terminal 182 interposed therebetween. The output terminal of the power amplifier 141 is connected to the matching circuit 173. The power amplifier 141 is controlled by, for example, a controller.

The power amplifier 142 is an amplifier that amplifies a transmission signal. More specifically, the power amplifier 142 amplifies a transmission signal in the second communication band. The power amplifier 142 is provided between the second transmission filter 131 and the second input terminal 183. The power amplifier 142 includes an input terminal and an output terminal. The input terminal of the power amplifier 142 is connected to the external circuit (for example, the signal processing circuit 2) with the second input terminal 183 interposed therebetween. The output terminal of the power amplifier 142 is connected to the matching circuit 174. The power amplifier 142 is controlled by, for example, a controller.

### (2.5) Low-Noise Amplifier

The low-noise amplifier 151 is an amplifier that amplifies a reception signal with a low noise. More specifically, the low-noise amplifier 151 amplifies a reception signal in the first communication band. The low-noise amplifier 151 is provided between the first reception filter 122 and the output terminal 184. The low-noise amplifier 151 includes an input terminal and an output terminal. The input terminal of the low-noise amplifier 151 is connected to the matching circuit 175. The output terminal of the low-noise amplifier 151 is connected to an external circuit (for example, the signal processing circuit 2) with the selection terminal 161 of the second switch 16 interposed therebetween.

The low-noise amplifier 152 is an amplifier that amplifies a reception signal with a low noise. More specifically, the low-noise amplifier 152 amplifies a reception signal in the second communication band. The low-noise amplifier 152 is provided between the second reception filter 132 and the output terminal 184. The low-noise amplifier 152 includes an input terminal and an output terminal. The input terminal of the low-noise amplifier 152 is connected to the matching circuit 176. The output terminal of the low-noise amplifier 152 is connected to an external circuit (for example, the signal processing circuit 2) with the selection terminal 162 of the second switch 16 interposed therebetween.

### (2.6) Second Switch

As shown in FIG. 3, the second switch 16 is a switch for switching a path connected to the output terminal 184 from among the low-noise amplifier 151 and the low-noise amplifier 152. That is, the second switch 16 is a switch for switching a path to be connected to the output terminal 184. The second switch 16 has a common terminal 160 and a plurality of (two in the shown example) selection terminals 161 and 162.

The common terminal 160 is connected to the output terminal 184. The selection terminal 161 is connected to the low-noise amplifier 151. In addition, the selection terminal 162 is connected to the low-noise amplifier 152.

The second switch 16 switches the connection between the common terminal 160, and the plurality of selection terminals 161 and 162. The second switch 16 is controlled by, for example, the signal processing circuit 2. The second switch 16 electrically connects the common terminal 160 to any one of the plurality of selection terminals 161 and 162 in accordance with a control signal from the RF signal processing circuit 21 of the signal processing circuit 2.

### (2.7) Matching Circuit

The plurality of matching circuits 171 to 176 are circuits for performing impedance matching of a circuit connected with each of the matching circuits 171 to 176 interposed therebetween. The matching circuit 171 is provided between the first switch 11, and the first transmission filter 121 and the first reception filter 122. The matching circuit 172 is provided between the first switch 11, and the second transmission filter 131 and the second reception filter 132. The matching circuit 173 is provided between the first transmission filter 121 and the power amplifier 141. The matching circuit 174 is provided between the second transmission filter 131 and the power amplifier 142. The matching circuit 175 is provided between the first reception filter 122 and the low-noise amplifier 151. The matching circuit 176 is provided between the second reception filter 132 and the low-noise amplifier 152.

Each of the matching circuits 171 to 176 has a configuration including, for example, one or more inductors or one or more capacitors.

### (2.8) External Connection Terminal

The plurality of external connection terminals 18 are terminals for electrical connection to an external circuit (for example, the signal processing circuit 2). The plurality of external connection terminals 18 include the antenna terminal 181, the first input terminal 182, the second input terminal 183, the output terminal 184, a plurality of control terminals, and a plurality of ground terminals.

The antenna terminal 181 is connected to an antenna 3. In the radio frequency module 1, the antenna terminal 181 is connected to the common terminal 110 of the first switch 11.

The first input terminal 182 is a terminal for inputting a transmission signal from the external circuit (for example, the signal processing circuit 2) to the radio frequency module 1. More specifically, the first input terminal 182 receives an input of a transmission signal in the first communication band. In the radio frequency module 1, the first input terminal 182 is connected to the input terminal of the power amplifier 141.

The second input terminal 183 is a terminal for inputting a transmission signal from the external circuit (for example, the signal processing circuit 2) to the radio frequency module 1. More specifically, the second input terminal 183 receives an input of a transmission signal in the second communication band. In the radio frequency module 1, the second input terminal 183 is connected to the input terminal of the power amplifier 142.

The output terminal 184 is a terminal for outputting a reception signal from the radio frequency module 1 to the external circuit (for example, the signal processing circuit 2). More specifically, the output terminal 184 outputs a reception signal in the first communication band or a reception signal in the second communication band. In the radio frequency module 1, the output terminal 184 is connected to the common terminal 160 of the second switch 16.

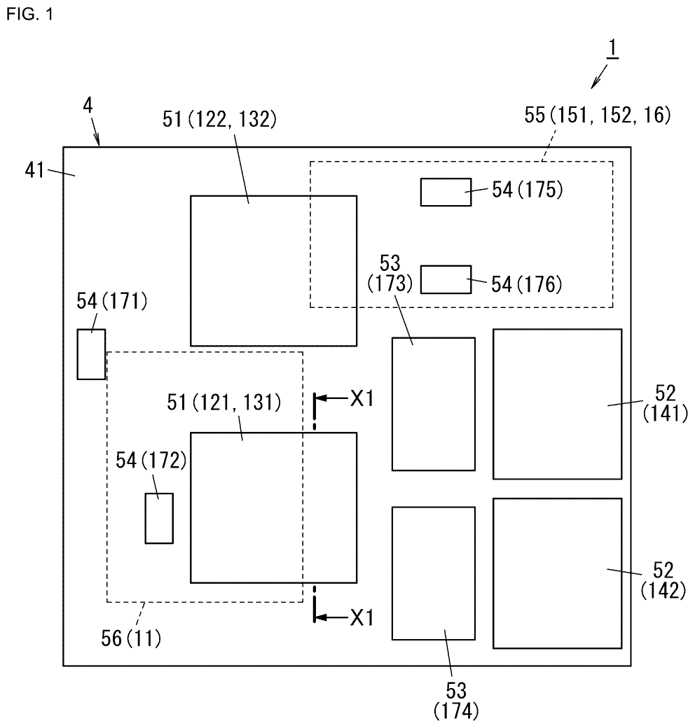

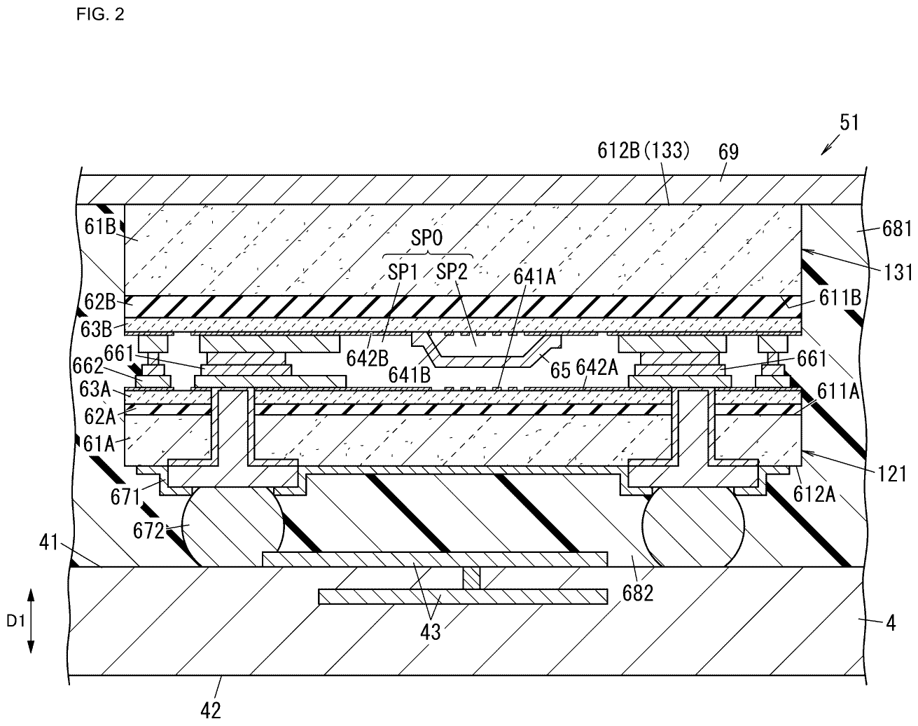

The plurality of ground terminals are terminals that are electrically connected to a ground electrode of an external board included in the communication device 10, and to which a ground potential is applied. In the radio frequency module 1, the plurality of ground terminals are connected to a ground electrode 43 (see FIG. 2) of a mounting board 4 (see FIG. 1). The ground electrode 43 is a circuit ground of the radio frequency module 1.

### (3) Structure of Radio Frequency Module

Next, a structure of the radio frequency module 1 according to exemplary embodiment 1 will be described with reference to FIGS. 1 and 2.

As shown in FIGS. 1 and 2, the radio frequency module 1 includes the mounting board 4, a plurality of (two in the shown example) first electronic components 51, a plurality of (two in the shown example) second electronic components 52, a plurality of (two in the shown example) third electronic components 53, a plurality of (four in the shown example) fourth electronic components 54, a fifth electronic component 55, and a sixth electronic component 56. In addition, as shown in FIG. 2, the radio frequency module 1 further includes a first resin layer 681, a second resin layer 682, and a first shield electrode 69.

The radio frequency module 1 is electrically connected to an external board. The external board is, for example, a mother board of the communication device 10 (see FIG. 3) that is a mobile phone, a communication device, or the like, for example.

### (3.1) Mounting Board

As shown in FIGS. 1 and 2, the mounting board 4 has a main surface 41 and a main surface 42. The main surface 41 and the main surface 42 face each other in a thickness direction D1 (see FIG. 2) of the mounting board 4 (also referred to as a “first direction D1” below). When the radio frequency module 1 is provided at an external board, the main surface 42 faces a main surface of the external board on the mounting board 4 side. The mounting board 4 is a double-sided mounting board in which the first electronic component 51, the second electronic component 52, the third electronic component 53, and the fourth electronic component 54 are mounted on the main surface 41, and the fifth electronic component 55 and the sixth electronic component 56 are mounted on the main surface 42.

The mounting board 4 is a multilayer substrate in which a plurality of dielectric layers are laminated. The mounting board 4 has a plurality of conductive layers and a plurality of via conductors (including through-electrodes). The plurality of conductive layers include the ground electrode 43 having a ground potential. In the present exemplary embodiment, the ground electrode 43 is a first ground electrode. The plurality of via conductors are used for electrical connection between the elements (including the first electronic component 51, the second electronic component 52, the third electronic component 53, the fourth electronic component 54, the fifth electronic component 55, and the sixth electronic component 56 described above) mounted on both the main surface 41 and the main surface 42 and the conductive layers of the mounting board 4.

### (3.2) First Electronic Component

As illustrated in FIGS. 1 and 2, the plurality of first electronic components 51 are disposed at the main surface 41 of the mounting board 4. The first electronic component 51 includes two acoustic wave filters. A combination of the two acoustic wave filters included in one (first) first electronic component 51 is a combination of the first transmission filter 121 and the second transmission filter 131. In addition, a combination of the two acoustic wave filters included in the other (second) first electronic component 51 is a combination of the first reception filter 122 and the second reception filter 132.

Each of the two acoustic wave filters included in the first electronic component 51 is, for example, an acoustic wave filter including a plurality of series arm resonators and a plurality of parallel arm resonators. For example, the acoustic wave filter is a surface acoustic wave (SAW) filter using a surface acoustic wave. Further, each of the two acoustic wave filters included in the first electronic component 51 may include at least one of an inductor and a capacitor connected in series to any of the plurality of series arm resonators. In addition, each of the two acoustic wave filters included in the first electronic component 51 may include an inductor or a capacitor connected in series to any of the plurality of parallel arm resonators.

In addition, in a plan view from the thickness direction D1 of the mounting board 4, the first electronic component 51 including the first transmission filter 121 and the second transmission filter 131 overlap the ground electrode 43 of the mounting board 4. Here, the phrase that the first electronic component 51 overlaps the ground electrode 43 of the mounting board 4 in a plan view from the thickness direction D1 of the mounting board 4 means that, in a plan view from the thickness direction D1 of the mounting board 4, there is a region including at least a part of the first electronic component 51 and at least a part of the ground electrode 43.

### (3.3) Second Electronic Component

As shown in FIG. 1, each of the plurality of second electronic components 52 is disposed at the main surface 41 of the mounting board 4. In the example of FIG. 1, each of the plurality of second electronic components 52 is mounted on the main surface 41 of the mounting board 4. Some or all of the plurality of second electronic components 52 may be mounted on the main surface 42 of the mounting board 4. The plurality of second electronic components 52 include, for example, the power amplifier 141 and the power amplifier 142.

### (3.4) Third Electronic Component

As shown in FIG. 1, each of the third electronic components 53 is disposed at the main surface 41 of the mounting board 4. The third electronic component 53 is mounted on the main surface 41 of the mounting board 4. The third electronic component 53 is, for example, an inductor constituting the matching circuit 173 (see FIG. 3) provided in a path between the first transmission filter 121 and the power amplifier 141. The matching circuit is a circuit for performing impedance matching between the first transmission filter 121 and the power amplifier 141. In addition, the third electronic component 53 is, for example, an inductor constituting the matching circuit 174 (see FIG. 3) provided in a path between the second transmission filter 131 and the power amplifier 142. The matching circuit is a circuit for performing impedance matching between the second transmission filter 131 and the power amplifier 142. The inductor is, for example, a chip inductor.

### (3.5) Fourth Electronic Component

As shown in FIG. 1, each of the fourth electronic components 54 is disposed at the main surface 41 of the mounting board 4. The fourth electronic component 54 is mounted on the main surface 41 of the mounting board 4. The fourth electronic component 54 is, for example, a capacitor constituting the matching circuit 171 (see FIG. 3) provided in a path between the selection terminal 111 of the first switch 11, and the first transmission filter 121 and the first reception filter 122. The matching circuit 171 is a circuit for performing impedance matching between the first transmission filter 121 and the first reception filter 122, and the antenna 3. In addition, the fourth electronic component 54 is, for example, a capacitor constituting the matching circuit 172 (see FIG. 3) provided in a path between the selection terminal 112 of the first switch 11, and the second transmission filter 131 and the second reception filter 132. The matching circuit 172 is a circuit for performing impedance matching between the second transmission filter 131 and the second reception filter 132, and the antenna 3. In addition, the fourth electronic component 54 is, for example, a capacitor constituting the matching circuit 175 (see FIG. 3) provided in a path between the first reception filter 122 and the low-noise amplifier 151. The matching circuit 175 is a circuit for performing impedance matching between the first reception filter 122 and the low-noise amplifier 151. In addition, the fourth electronic component 54 is, for example, a capacitor constituting the matching circuit 176 (see FIG. 3) provided in a path between the second reception filter 132 and the low-noise amplifier 152. The matching circuit 176 is a circuit for performing impedance matching between the second reception filter 132 and the low-noise amplifier 152.

### (3.6) Fifth Electronic Component

As shown in FIG. 1, the fifth electronic component 55 is disposed at the main surface 42 of the mounting board 4. The fifth electronic component 55 is mounted on the main surface 42 of the mounting board 4. The fifth electronic component 55 includes the low-noise amplifier 151, the low-noise amplifier 152, and the second switch 16.

### (3.7) Sixth Electronic Component

As shown in FIG. 1, the sixth electronic component 56 is disposed at the main surface 42 of the mounting board 4. The sixth electronic component 56 is mounted on the main surface 42 of the mounting board 4. The sixth electronic component 56 is an IC including the first switch 11.

### (3.8) First Resin Layer, Second Resin Layer, and First Shield Electrode

The first resin layer 681 (see FIG. 2) covers a side surface of the first electronic component 51 and the like. More specifically, the first resin layer 681 covers at least a part of the first transmission filter 121 and the second transmission filter 131 in the first electronic component 51.

The second resin layer 682 (see FIG. 2) covers the ground electrode 43 of the mounting board 4. More specifically, the second resin layer 682 is located between the first transmission filter 121 and the ground electrode 43 of the mounting board 4, in the first electronic component 51.

The first shield electrode 69 (see FIG. 2) covers a part of the first resin layer 681. More specifically, the first shield electrode 69 is in contact with a main surface 133 (see FIG. 2) of the first electronic component 51 on an opposite side from the first transmission filter 121 side of the second transmission filter 131.

### (4) Detailed Structure of Each Constituent Element of Radio Frequency Module

### (4.1) Mounting Board

The mounting board 4 shown in FIGS. 1 and 2 is, for example, a multilayer substrate including a plurality of dielectric layers and a plurality of conductive layers. The plurality of dielectric layers and the plurality of conductive layers are laminated in the thickness direction D1 of the mounting board 4. The plurality of conductive layers are formed in a predetermined pattern determined for each layer. Each of the plurality of conductive layers includes one or a plurality of conductor portions in one plane perpendicular to the thickness direction D1 of the mounting board 4. A material of each conductive layer is, for example, copper. The plurality of conductive layers include a ground layer. In the radio frequency module 1, the plurality of ground terminals and the ground layer are electrically connected to each other with the via conductor and the like of the mounting board 4 interposed therebetween. The mounting board 4 is, for example, a low temperature co-fired ceramics (LTCC) substrate. The mounting board 4 is not limited to the LTCC substrate, and may be, for example, a printed wiring board, a high temperature co-fired ceramics (HTCC) substrate, or a resin multilayer substrate.

Further, the mounting board 4 is not limited to the LTCC substrate, and may be, for example, a wiring structural body. The wiring structural body is, for example, a multilayer structural body. The multilayer structural body includes at least one insulating layer and at least one conductive layer. The insulating layer is formed in a predetermined pattern. In a case where a plurality of insulating layers are provided, the plurality of insulating layers are formed in a predetermined pattern determined for each layer. The conductive layer is formed in a predetermined pattern different from the predetermined pattern of the insulating layer. In a case where a plurality of conductive layers are provided, the plurality of conductive layers are formed in a predetermined pattern determined for each layer. The conductive layer may include one or a plurality of rewiring portions. In the wiring structural body, a first surface of two surfaces facing each other in a thickness direction of the multilayer structural body is the main surface 41 of the mounting board 4, and a second surface is the main surface 42 of the mounting board 4. The wiring structural body may be, for example, an interposer. The interposer may be an interposer using a silicon substrate or may be a substrate constituted by multiple layers.

The main surface 41 and the main surface 42 of the mounting board 4 are separated in the thickness direction D1 of the mounting board 4, and intersect with the thickness direction D1 of the mounting board 4. The main surface 41 of the mounting board 4 is, for example, perpendicular to the thickness direction D1 of the mounting board 4, and may include, for example, a side surface or the like of a conductor portion as a surface that is not perpendicular to the thickness direction D1 of the mounting board 4. In addition, the main surface 42 of the mounting board 4 is, for example, perpendicular to the thickness direction D1 of the mounting board 4, and may include, for example, a side surface or the like of a conductor portion as a surface that is not perpendicular to the thickness direction D1 of the mounting board 4. In addition, fine irregularities, recesses, or protrusions may be formed in the main surface 41 and the main surface 42 of the mounting board 4.

### (4.2) First Electronic Component

A detailed structure of the first electronic component 51 shown in FIG. 2 will be described. In the following description, the first electronic component 51 including the first transmission filter 121 and the second transmission filter 131 among the plurality of (two in FIG. 1) first electronic components 51 will be described, but the other first electronic components 51 also have the similar structure.

The first electronic component 51 includes the first transmission filter 121 and the second transmission filter 131 as two acoustic wave filters. As shown in FIG. 2, the first electronic component 51 includes a first substrate 61A, a first low acoustic velocity film 62A, a first piezoelectric layer 63A, and a first circuit portion 642A. The first substrate 61A includes a main surface 611A and a main surface 612A facing each other in a thickness direction of the first substrate 61A. The first circuit portion 642A includes a plurality of first interdigital transducer (IDT) electrodes 641A. In addition, the first circuit portion 642A includes a ground electrode. The ground electrode of the first circuit portion 642A is connected to the ground electrode 43 of the mounting board 4. In the present disclosure, the ground electrode of the first circuit portion 642A is electrically connected to the ground electrode 43 of the mounting board 4. Some of the plurality of first IDT electrodes 641A are electrically connected to the ground electrode 43 of the mounting board 4 via the ground electrode of the first circuit portion 642A. In the present exemplary embodiment, the plurality of first IDT electrodes 641A are first functional electrodes. In addition, in the present exemplary embodiment, the ground electrode is a second ground electrode. The first low acoustic velocity film 62A is provided on the main surface 611A of the first substrate 61A. That is, in the present exemplary embodiment, the first substrate 61A is a first support member. The plurality of first IDT electrodes 641A are provided on the first piezoelectric layer 63A. The first transmission filter 121 includes the first substrate 61A, the first low acoustic velocity film 62A, the first piezoelectric layer 63A, the plurality of first IDT electrodes 641A, and the first circuit portion 642A.

As shown in FIG. 2, the first electronic component 51 further includes a second substrate 61B, a second low acoustic velocity film 62B, a second piezoelectric layer 63B, and a second circuit portion 642B. The second substrate 61B includes a main surface 611B and a main surface 612B facing each other in a thickness direction of the second substrate 61B. The second circuit portion 642B includes a plurality of second IDT electrodes 641B. In addition, the second circuit portion 642B includes a ground electrode. The ground electrode of the second circuit portion 642B is connected to the ground electrode 43 of the mounting board 4. In the present disclosure, the ground electrode of the second circuit portion 642B is electrically connected to the ground electrode 43 of the mounting board 4. In the present exemplary embodiment, the plurality of second IDT electrodes 641B are second functional electrodes. In addition, in the present exemplary embodiment, the ground electrode is a third ground electrode. The second low acoustic velocity film 62B is provided on the main surface 611B of the second substrate 61B. That is, in the present exemplary embodiment, the second substrate 61B is a second support member. The plurality of second IDT electrodes 641B are provided on the second piezoelectric layer 63B. The second transmission filter 131 includes the second substrate 61B, the second low acoustic velocity film 62B, the second piezoelectric layer 63B, and the second circuit portion 642B. In addition, in the second transmission filter 131, the main surface 133 on an opposite side from the first transmission filter 121 side is the main surface 612B of the second substrate 61B.

The materials of the first piezoelectric layer 63A and the second piezoelectric layer 63B are, for example, lithium niobate or lithium tantalate. The materials of the first low acoustic velocity film 62A and the second low acoustic velocity film 62B are, for example, silicon oxide. In the first low acoustic velocity film 62A, the acoustic velocity of a bulk wave propagating in the first low acoustic velocity film 62A is lower than the acoustic velocity of a bulk wave propagating in the first piezoelectric layer 63A. In addition, in the second low acoustic velocity film 62B, the acoustic velocity of a bulk wave propagating in the second low acoustic velocity film 62B is lower than the acoustic velocity of a bulk wave propagating in the second piezoelectric layer 63B. The materials of the first low acoustic velocity film 62A and the second low acoustic velocity film 62B are not limited to silicon oxide, and may be, for example, silicon oxide, glass, silicon oxynitride, tantalum oxide, a compound obtained by adding fluorine, carbon, or boron to silicon oxide, or a material containing the above-described materials as a main component.

Each of the first substrate 61A and the second substrate 61B is, for example, a silicon substrate. That is, the materials of the first substrate 61A and the second substrate 61B of the first electronic component 51 are silicon. In the first substrate 61A, the acoustic velocity of a bulk wave propagating in the first substrate 61A is higher than the acoustic velocity of a bulk wave propagating in the first piezoelectric layer 63A. Here, the bulk wave propagating in the first substrate 61A is a bulk wave having the lowest acoustic velocity among a plurality of bulk waves propagating in the first substrate 61A. In the present exemplary embodiment, a high acoustic velocity member is constituted by the first substrate 61A and the first low acoustic velocity film 62A provided on the first substrate 61A. In addition, in the present exemplary embodiment, the first substrate 61A is a first support substrate formed of a silicon substrate. Similarly, in the second substrate 61B, the acoustic velocity of a bulk wave propagating in the second substrate 61B is higher than the acoustic velocity of a bulk wave propagating in the second piezoelectric layer 63B. Here, the bulk wave propagating in the second substrate 61B is a bulk wave having the lowest acoustic velocity among a plurality of bulk waves propagating in the second substrate 61B. In addition, in the present exemplary embodiment, the second substrate 61B is a second support substrate formed of a silicon substrate. In addition, the materials of the first substrate 61A and the second substrate 61B are not limited to silicon, and may be, for example, materials containing, as a main component, any one of aluminum nitride, aluminum oxide, silicon carbide, silicon nitride, sapphire, lithium tantalate, lithium niobate, quartz, alumina, zirconia, cordierite, mullite, steatite, forsterite, magnesia, and diamond.

The main surface 611A of the first substrate 61A and the main surface 611B of the second substrate 61B face each other in the first direction D1. That is, the second transmission filter 131 is disposed on the first transmission filter 121. In addition, as shown in FIG. 2, the first electronic component 51 further includes a plurality of conductors 661 that are stretched in a direction intersecting with the first direction D1 and a frame 662. The plurality of conductors 661 and the frame 662 are electrodes for electrically connecting the second transmission filter 131 and the mounting board 4 to each other. The plurality of conductors 661 include, for example, columnar (for example, prismatic) electrodes. In addition, the frame 662 is a frame-shaped electrode. The materials of the plurality of conductors 661 and the frame 662 are, for example, metal (for example, copper, a copper alloy, or the like). The plurality of conductors 661 and the frame 662 are located between the first substrate 61A and the second substrate 61B. A hollow space SP0 is formed inside the frame 662 between the first substrate 61A and the second substrate 61B. The plurality of first IDT electrodes 641A and the plurality of second IDT electrodes 641B are disposed in the hollow space SP0. At least the frame 662 or some of the plurality of conductors 661 is connected to the ground electrode 43 of the mounting board 4 with a via conductor 671 and a bump 672 interposed therebetween. The via conductor 671 penetrate the first substrate 61A. The frame 662 does not need to be an electrode. In a case where the frame 662 is not an electrode, the material of the frame 662 may be an insulator such as a resin.

In addition, as shown in FIG. 2, the first electronic component 51 further includes a second shield electrode 65. The second shield electrode 65 is, for example, a shield electrode provided between the first IDT electrode 641A and the second IDT electrode 641B, for the purpose of electromagnetic shielding. The second shield electrode 65 is one metal layer, but is not limited to one metal layer, and may have a multilayer structure in which a plurality of metal layers are laminated. The second shield electrode 65 is located in the hollow space SP0 and covers at least one of the first IDT electrode 641A or the second IDT electrode 641B. The second shield electrode 65 in exemplary embodiment 1 covers the second IDT electrode 641B. More specifically, in a plan view from the first direction D1, the second shield electrode 65 overlaps the first IDT electrode 641A and overlaps the second IDT electrode 641B. The second shield electrode 65 divides the hollow space SP0 into a first space SP1 and a second space SP2. The first IDT electrode 641A is located in the first space SP1, and the second IDT electrode 641B is located in the second space SP2. The first space SP1 and the second space SP2 do not need to be completely isolated by the second shield electrode 65, and the first space SP1 and the second space SP2 may communicate with each other on the surface of the second piezoelectric layer 63B.

### (4.3) Resin Layer

A relationship between the first resin layer 681 and the second resin layer 682, and the first electronic component 51 will be described below in detail.

The first resin layer 681 covers at least a part of the first transmission filter 121 and the second transmission filter 131 in the first electronic component 51. Here, the first resin layer 681 covers the outer peripheral surface of each of the first substrate 61A, the first low acoustic velocity film 62A, the first piezoelectric layer 63A, the conductor 661, the frame 662, the second piezoelectric layer 63B, the second low acoustic velocity film 62B, and the second substrate 61B.

The second resin layer 682 is located between the first substrate 61A and the mounting board 4 in the first electronic component 51. More specifically, the second resin layer 682 is disposed between the main surface 612A of the first substrate 61A and the main surface 41 of the mounting board 4. Here, the second resin layer 682 may be located on the ground electrode 43 of the mounting board 4.

The first resin layer 681 and the second resin layer 682 contains a resin (for example, an epoxy resin). The first resin layer 681 and the second resin layer 682 may contain a filler in addition to the resin.

### (4.4) First Shield Electrode

A relationship between the first shield electrode 69 and the first electronic component 51 will be described below in detail.

The first shield electrode 69 covers at least a part of the first resin layer 681. Here, the first shield electrode 69 is in contact with the main surface 133 of the second transmission filter 131 in the first electronic component 51.

The first shield electrode 69 has a multilayer structure in which a plurality of metal layers are laminated, but is not limited to the multilayer structure, and may be one metal layer. One metal layer includes one type or a plurality of types of metal.

### (5) Communication Device

As shown in FIG. 3, the communication device 10 includes the radio frequency module 1, the antenna 3, and the signal processing circuit 2.

### (5.1) Antenna

The antenna 3 is connected to the antenna terminal 181 of the radio frequency module 1. The antenna 3 has a transmission function of emitting a transmission signal output from the radio frequency module 1 as radio waves, and a reception function of receiving a reception signal from an outside as radio waves and outputting the reception signal to the radio frequency module 1.

### (5.2) Signal Processing Circuit

The signal processing circuit 2 includes the RF signal processing circuit 21 and a baseband signal processing circuit 22. The signal processing circuit 2 processes a signal passing through the radio frequency module 1. More specifically, the signal processing circuit 2 processes the transmission signal and the reception signal.

For example, the RF signal processing circuit 21 is a radio frequency integrated circuit (RFIC). The RF signal processing circuit 21 performs signal processing on a radio frequency signal.

The RF signal processing circuit 21 performs signal processing such as up-conversion on a radio frequency signal output from the baseband signal processing circuit 22, and outputs the radio frequency signal subjected to the signal processing to the radio frequency module 1. Specifically, the RF signal processing circuit 21 performs signal processing such as up-conversion on the transmission signal output from the baseband signal processing circuit 22, and outputs the transmission signal subjected to the signal processing to the first input terminal 182 or the second input terminal 183 of the radio frequency module 1.

The RF signal processing circuit 21 performs signal processing such as down-conversion on a radio frequency signal output from the radio frequency module 1, and outputs the radio frequency signal subjected to the signal processing to the baseband signal processing circuit 22. Specifically, the RF signal processing circuit 21 performs signal processing on the reception signal output from the output terminal 184 of the radio frequency module 1, and outputs the reception signal subjected to the signal processing to the baseband signal processing circuit 22.

For example, the baseband signal processing circuit 22 is a baseband integrated circuit (BBIC). The baseband signal processing circuit 22 performs predetermined signal processing on the transmission signal from the outside of the signal processing circuit 2. The reception signal processed by the baseband signal processing circuit 22 is used, for example, as an image signal for an image display or as an audio signal for a call.

In addition, the RF signal processing circuit 21 also has a function as a control unit that controls each of the first switch 11 and the second switch 16 included in the radio frequency module 1 based on the transmission and reception of the radio frequency signals (transmission signal and reception signal). Specifically, the RF signal processing circuit 21 switches the connection of each of the first switch 11 and the second switch 16 of the radio frequency module 1 by a control signal. The control unit may be provided outside the RF signal processing circuit 21, and may be provided in the radio frequency module 1 or the baseband signal processing circuit 22, for example.

### (6) Details of First Shield Electrode and Second Shield Electrode

The first shield electrode 69 and the second shield electrode 65 will be described in detail with reference to the drawings.

As shown in FIG. 2, in the radio frequency module 1 according to exemplary embodiment 1, the main surface 133 of the second transmission filter 131 on an opposite side from the first transmission filter 121 is in contact with the first shield electrode 69. As a result, heat generated in the second transmission filter 131 is dissipated to the first shield electrode 69 side. Thus, it is possible to reduce the influence of the heat generated in the second transmission filter 131 on the first transmission filter 121.

In addition, in the radio frequency module 1 according to exemplary embodiment 1, the first IDT electrode 641A and the ground electrode 43 of the mounting board 4 are electrically connected to each other. Thus, heat generated in the first IDT electrode 641A is dissipated to the ground electrode 43 of the mounting board 4 through electrical connection. In addition, in the radio frequency module 1 according to exemplary embodiment 1, the ground electrode of the first transmission filter 121 and the ground electrode of the second transmission filter 131 are connected to the ground electrode 43 of the mounting board 4 with the conductor 661, the frame 662, the via conductor 671, and the bump 672 interposed therebetween. Thus, the heat generated in the first IDT electrode 641A is likely to be dissipated to the ground electrode 43 of the mounting board 4 that is electrically connected. Further, in the radio frequency module 1 according to exemplary embodiment 1, there is the second resin layer 682 between the first transmission filter 121 and the ground electrode 43 of the mounting board 4. In addition, in the radio frequency module 1 according to exemplary embodiment 1, in a plan view from the thickness direction D1 of the mounting board 4, the first transmission filter 121 and the ground electrode 43 of the mounting board 4 overlap each other. Thus, the heat generated in the first IDT electrode 641A is likely to be dissipated to the ground electrode 43 of the mounting board 4 that is electrically connected. As a result, it is possible to reduce the influence of the heat generated in the first transmission filter 121 on the second transmission filter 131.

In addition, as shown in FIG. 2, in the radio frequency module 1 according to exemplary embodiment 1, the second shield electrode 65 covers the second IDT electrode 641B. As a result, the second shield electrode 65 functions as a shield between the first space SP1 in which the first IDT electrode 641A is located and the second space SP2 in which the second IDT electrode 641B is located. Thus, it is possible to hinder the transfer of heat between the first transmission filter 121 and the second transmission filter 131. Further, it is possible to improve isolation between the first transmission filter 121 and the second transmission filter 131.

### (7) Effects

In the radio frequency module 1 according to exemplary embodiment 1, the first resin layer 681 covers at least a part of the first transmission filter 121 and the second transmission filter 131, and the first shield electrode 69 covers at least a part of the first resin layer 681. Thus, it is possible to dissipate the heat generated in the first transmission filter 121 and the second transmission filter 131 through the first shield electrode 69.

In addition, in the radio frequency module 1 according to exemplary embodiment 1, the first shield electrode 69 is in contact with the main surface 133 of the second transmission filter 131 on an opposite side from the first transmission filter 121 side. Thus, the heat generated in the acoustic wave resonator of the second transmission filter 131 is dissipated from the first shield electrode 69. Thus, the heat dissipation properties of the second transmission filter 131 are improved, and it is possible to reduce the influence of the heat generated in the second transmission filter 131 on the first transmission filter 121.

In addition, in the radio frequency module 1 according to exemplary embodiment 1, the conductor 661 located between the second substrate 61B and the first substrate 61A and the via conductor 671 that penetrates the first substrate 61A in the first direction D1 are connected to the ground electrode 43 of the mounting board 4. Thus, the conductor 661 and the via conductor 671 function as a heat conduction path from the first IDT electrode 641A to the ground electrode 43. Thus, it is possible to reduce the conduction of the heat generated in the first transmission filter 121 to the second transmission filter 131.

In addition, in the radio frequency module 1 according to exemplary embodiment 1, the maximum output power of the power class of the signal passing through the second transmission filter 131 is higher than the maximum output power of the power class of the signal passing through the first transmission filter 121. Thus, the heat generation by the second transmission filter 131 is greater than the heat generation by the first transmission filter 121. As described above, in the radio frequency module 1 according to exemplary embodiment 1, since the heat generation of the second transmission filter 131 is dissipated from the first shield electrode 69, the heat dissipation properties of the second transmission filter 131 are higher than the heat dissipation properties of the first transmission filter 121. Thus, it is possible to reduce the influence of the heat generated in the second transmission filter 131 on the first transmission filter 121 and the second transmission filter 131.

In addition, in the radio frequency module 1 according to exemplary embodiment 1, the second shield electrode 65 is located in the hollow space SP0 and covers at least one of the first IDT electrode 641A that is the first functional electrode, and the second IDT electrode 641B that is the second functional electrode. Thus, it is possible to hinder the transfer of heat between the first transmission filter 121 and the second transmission filter 131. Further, it is possible to improve isolation between the first transmission filter 121 and the second transmission filter 131.

### Exemplary Embodiment 2

A radio frequency module 1 according to exemplary embodiment 2 will be described. Regarding the radio frequency module 1 according to exemplary embodiment 2, the similar configuration to the radio frequency module 1 according to exemplary embodiment 1 is denoted by the same reference numerals, and the description thereof will be omitted.

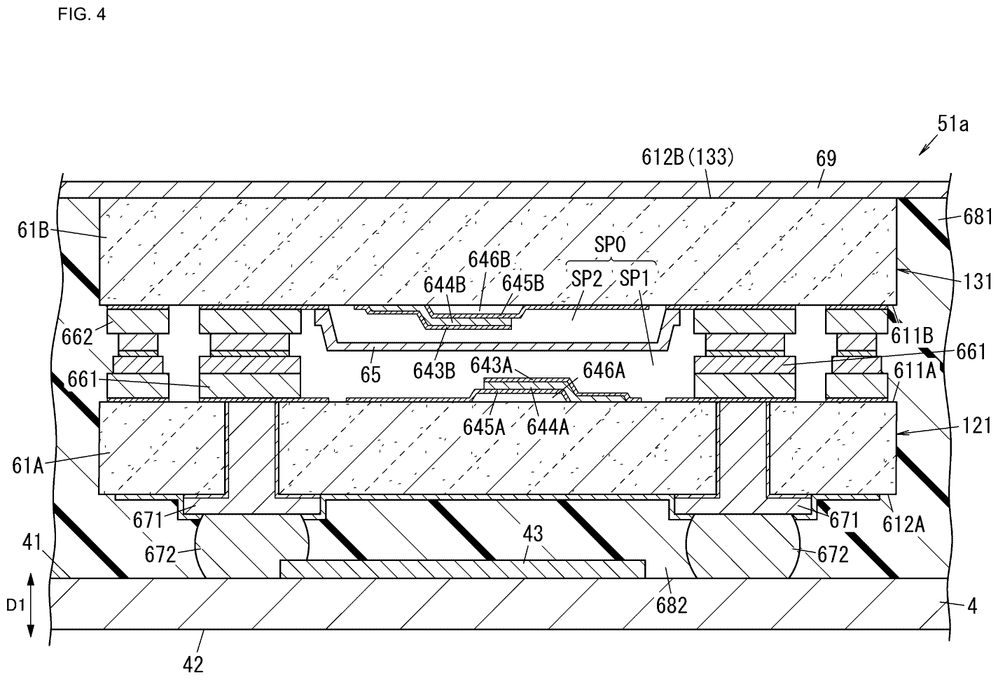

The radio frequency module 1 according to exemplary embodiment 2 includes a first electronic component 51a instead of the first electronic component 51. As shown in FIG. 4, the first electronic component 51a includes a bulk acoustic wave (BAW) filter as each of a first transmission filter 121 and a second transmission filter 131.

The detailed structure of the first electronic component 51a will be described. As shown in FIG. 4, the first electronic component 51a includes a first substrate 61A, a first upper electrode 643A, a first piezoelectric film 644A, and a first lower electrode 645A. In the present exemplary embodiment, the first upper electrode 643A is a first functional electrode. The material of the first piezoelectric film 644A is, for example, AlN, ScAlN, or PZT (lead zirconate titanate). The first lower electrode 645A has a cavity 646A between the first lower electrode 645A and the first substrate 61A. A BAW resonator included in the first transmission filter 121 is a film bulk acoustic resonator (FBAR), but is not limited to this, and may be a solidly mounted resonator (SMR). The first transmission filter 121 includes the first substrate 61A, the first upper electrode 643A, the first piezoelectric film 644A, and the first lower electrode 645A. The first upper electrode 643A, the first piezoelectric film 644A, and the first lower electrode 645A are located in a hollow space SP0 formed between a main surface 611A of the first substrate 61A and a main surface 611B of the second substrate 61B.

In addition, as shown in FIG. 4, the first electronic component 51a includes a second substrate 61B, a second upper electrode 643B, a second piezoelectric film 644B, and a second lower electrode 645B. In the present exemplary embodiment, the second upper electrode 643B is a second functional electrode. The material of the second piezoelectric film 644B is, for example, AlN, ScAlN, or PZT. The second lower electrode 645B has a cavity 646B between the second lower electrode 645B and the second substrate 61B. A BAW resonator included in the second transmission filter 131 is an FBAR, but is not limited to this, and may be an SMR. The second transmission filter 131 includes the second substrate 61B, the second upper electrode 643B, the second piezoelectric film 644B, and the second lower electrode 645B. The second upper electrode 643B, the second piezoelectric film 644B, and the second lower electrode 645B are located in the hollow space SP0.

In the radio frequency module 1 according to exemplary embodiment 2, a first resin layer 681 covers at least a part of the first transmission filter 121 and the second transmission filter 131, and a first shield electrode 69 covers at least a part of the first resin layer 681. Thus, it is possible to dissipate the heat generated in the first transmission filter 121 and the second transmission filter 131 through the first shield electrode 69.

In addition, in the radio frequency module 1 according to exemplary embodiment 2, the first shield electrode 69 is in contact with a main surface 133 of the second transmission filter 131. Thus, heat generated in the BAW resonator of the second transmission filter 131 is dissipated from the first shield electrode 69. Thus, the heat dissipation properties of the second transmission filter 131 are improved, and it is possible to reduce the influence of the heat generated in the second transmission filter 131 on the first transmission filter 121.

In addition, in the radio frequency module 1 according to exemplary embodiment 2, a conductor 661 located between the second substrate 61B and the first substrate 61A and a via conductor 671 that penetrates the first substrate 61A in the first direction D1 are connected to a ground electrode 43 of a mounting board 4. Thus, the conductor 661 and the via conductor 671 function as a heat conduction path from the first upper electrode 643A to the ground electrode 43. Thus, it is possible to reduce the conduction of the heat generated in the first transmission filter 121 to the second transmission filter 131.

In addition, in the radio frequency module 1 according to exemplary embodiment 2, the maximum output power of the power class of a signal passing through the second transmission filter 131 is higher than the maximum output power of the power class of a signal passing through the first transmission filter 121. Thus, the heat generation by the second transmission filter 131 is greater than the heat generation by the first transmission filter 121. As described above, in the radio frequency module 1 according to exemplary embodiment 2, since the heat generation of the second transmission filter 131 is dissipated from the first shield electrode 69, the heat dissipation properties of the second transmission filter 131 are higher than the heat dissipation properties of the first transmission filter 121. Thus, it is possible to reduce the influence of the heat generated in the second transmission filter 131 on the first transmission filter 121 and the second transmission filter 131.

In addition, in the radio frequency module 1 according to exemplary embodiment 2, the second shield electrode 65 covers one of the first upper electrode 643A and the second upper electrode 643B. Thus, in the radio frequency module 1 according to exemplary embodiment 2, it is possible to hinder the transfer of heat between the first transmission filter 121 and the second transmission filter 131. Further, it is possible to improve isolation between the first transmission filter 121 and the second transmission filter 131.

### Exemplary Embodiment 3

A radio frequency module 1 according to exemplary embodiment 3 will be described. Regarding the radio frequency module 1 according to exemplary embodiment 3, the similar configuration to the radio frequency module 1 according to exemplary embodiment 1 is denoted by the same reference numerals, and the description thereof will be omitted.

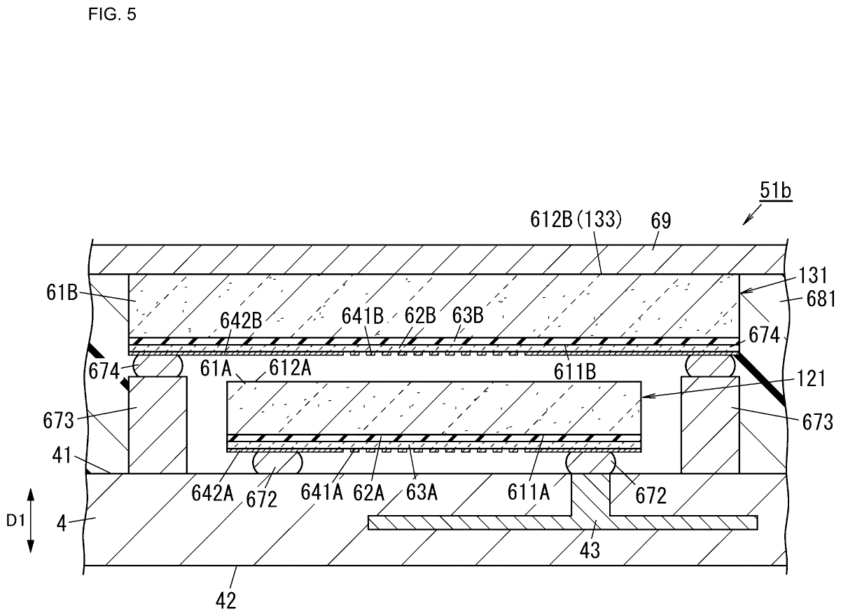

The radio frequency module 1 according to exemplary embodiment 3 includes a first electronic component 51b instead of the first electronic component 51. As shown in FIG. 5, the first electronic component 51b includes each of a first transmission filter 121 and a second transmission filter 131. Each of the first transmission filter 121 and the second transmission filter 131 is, for example, an acoustic wave filter including a plurality of series arm resonators and a plurality of parallel arm resonators.

A detailed structure of the first electronic component 51b will be described. As shown in FIG. 5, the first electronic component 51b includes a first substrate 61A, a first low acoustic velocity film 62A, a first piezoelectric layer 63A, and a first circuit portion 642A. The first substrate 61A includes a main surface 611A and a main surface 612A facing each other in a thickness direction of the first substrate 61A. The first circuit portion 642A includes a plurality of first IDT electrodes 641A. In the present exemplary embodiment, the plurality of first IDT electrodes 641A are first functional electrodes. The first low acoustic velocity film 62A is provided on the main surface 611A of the first substrate 61A. The plurality of first IDT electrodes 641A are provided on the first piezoelectric layer 63A. The first transmission filter 121 includes the first substrate 61A, the first low acoustic velocity film 62A, the first piezoelectric layer 63A, the plurality of first IDT electrodes 641A, and the first circuit portion 642A.

As shown in FIG. 5, the first electronic component 51b further includes a second substrate 61B, a second low acoustic velocity film 62B, a second piezoelectric layer 63B, and a second circuit portion 642B. The second substrate 61B includes a main surface 611B and a main surface 612B facing each other in a thickness direction of the second substrate 61B. The second circuit portion 642B includes a plurality of second IDT electrodes 641B. In the present exemplary embodiment, the plurality of second IDT electrodes 641B are second functional electrodes. The second low acoustic velocity film 62B is provided on the main surface 611B of the second substrate 61B. The second transmission filter 131 includes the second substrate 61B, the second low acoustic velocity film 62B, the second piezoelectric layer 63B, the plurality of second IDT electrodes 641B, and the second IDT electrode 641B.

The main surface 611A of the first substrate 61A and a main surface 41 of a mounting board 4 face each other in the first direction D1. In addition, as shown in FIG. 5, the first electronic component 51b includes a plurality of bumps 672. The plurality of bumps 672 are electrodes for electrically connecting the first transmission filter 121 and a mounting board 4 to each other. At least some of the plurality of bumps 672 are connected to a ground electrode 43 of the mounting board 4. The plurality of first IDT electrodes 641A are disposed in a space formed between the first substrate 61A and the mounting board 4.

In addition, the main surface 611B of the second substrate 61B and the main surface 612A of the first substrate 61A face each other in the first direction D1. In addition, as shown in FIG. 5, the first electronic component 51b includes a plurality of conductors 673 and a plurality of bumps 674. The plurality of conductors 673 and the plurality of bumps 674 are electrodes for electrically connecting the second transmission filter 131 and the mounting board 4. At least some of the plurality of conductors 673 and the plurality of bumps 674 are connected to the ground electrode 43 of the mounting board 4. The plurality of second IDT electrodes 641B are disposed in a space formed between the first substrate 61A and the second substrate 61B. In addition, a main surface 133 of the second transmission filter 131 on an opposite side from the first transmission filter 121 side is the main surface 612B of the second substrate 61B.

A first resin layer 681 covers at least a part of the first transmission filter 121 and the second transmission filter 131 in the first electronic component 51b. Here, the first resin layer 681 covers the outer peripheral surface of each of the conductors 673, the bumps 674, and the second substrate 61B.

A first shield electrode 69 covers at least a part of the first resin layer 681. Here, the first shield electrode 69 is in contact with the main surface 133 of the second transmission filter 131 on an opposite side from the first transmission filter 121 in the first electronic component 51b.

In the radio frequency module 1 according to exemplary embodiment 3, the first substrate 61A is located between the first IDT electrode 641A that is the first functional electrode, and the second IDT electrode 641B that is the second functional electrode. Thus, the first substrate 61A functions as a shield between the first IDT electrode 641A and the second IDT electrode 641B. Therefore, it is possible to hinder the transfer of heat between the first transmission filter 121 and the second transmission filter 131. Further, it is possible to improve isolation between the first transmission filter 121 and the second transmission filter 131.

In addition, in the radio frequency module 1 according to exemplary embodiment 3, the first resin layer 681 covers the outer peripheral surface of each of the conductors 673, the bumps 674, and the second substrate 61B, and the first shield electrode 69 covers at least a part of the first resin layer 681. Thus, it is possible to dissipate the heat generated in the second transmission filter 131 through the first shield electrode 69.

In addition, in the radio frequency module 1 according to exemplary embodiment 3, the first shield electrode 69 is in contact with the main surface 133 of the second transmission filter 131 on the opposite side from the first transmission filter 121 side. Thus, the heat generated in an acoustic wave resonator of the second transmission filter 131 is dissipated from the first shield electrode 69. Thus, the heat dissipation properties of the second transmission filter 131 are improved, and it is possible to reduce the influence of the heat generated in the second transmission filter 131 on the first transmission filter 121.

In addition, in the radio frequency module 1 according to exemplary embodiment 3, the first IDT electrode 641A faces the ground electrode 43 of the mounting board 4. Thus, the heat conduction from the first IDT electrode 641A to the ground electrode 43 is facilitated. Thus, it is possible to reduce the conduction of the heat generated in the first transmission filter 121 to the second transmission filter 131.

In addition, in the radio frequency module 1 according to exemplary embodiment 3, the maximum output power of the power class of a signal passing through the second transmission filter 131 is higher than the maximum output power of the power class of a signal passing through the first transmission filter 121. Thus, the heat generation by the second transmission filter 131 is greater than the heat generation by the first transmission filter 121. As described above, in the radio frequency module 1 according to exemplary embodiment 3, since the heat generation of the second transmission filter 131 is dissipated from the first shield electrode 69, the heat dissipation properties of the second transmission filter 131 are higher than the heat dissipation properties of the first transmission filter 121. Thus, it is possible to reduce the influence of the heat generated in the second transmission filter 131 on the first transmission filter 121 and the second transmission filter 131.

### Exemplary Embodiment 4

A radio frequency module 1 according to exemplary embodiment 4 will be described. Regarding the radio frequency module 1 according to exemplary embodiment 4, the similar configuration to the radio frequency module 1 according to exemplary embodiment 1 is denoted by the same reference numerals, and the description thereof will be omitted.

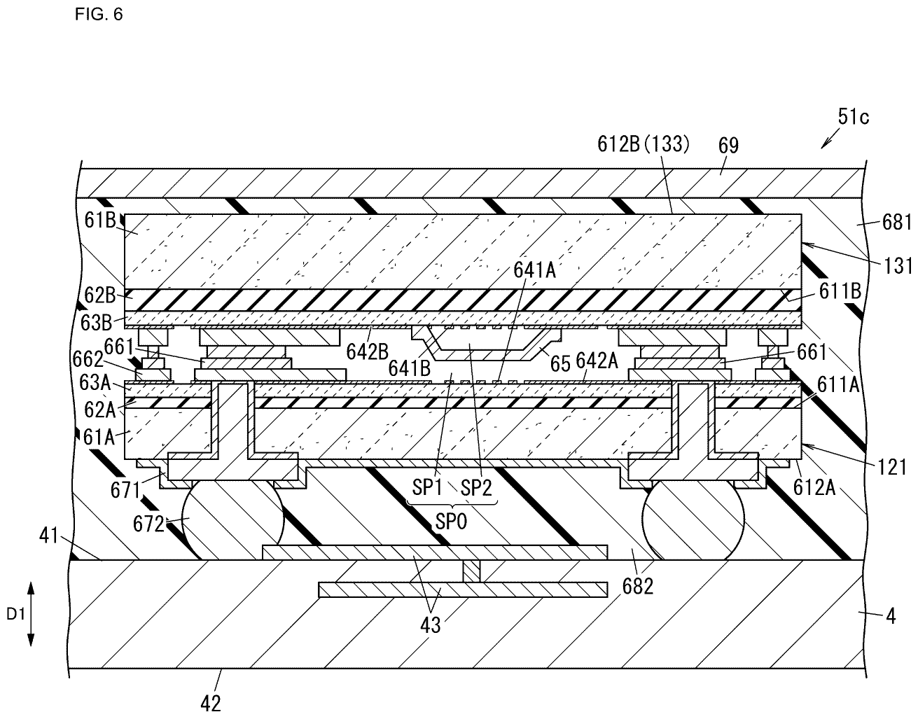

The radio frequency module 1 according to exemplary embodiment 4 includes a first electronic component 51c instead of the first electronic component 51. As shown in FIG. 6, in the first electronic component 51c, a main surface 133 of a second transmission filter 131 on an opposite side from a first transmission filter 121 side is not in contact with a first shield electrode 69.

The detailed structure of the first electronic component 51c will be described. The first electronic component 51c includes the first transmission filter 121 and the second transmission filter 131 as two acoustic wave filters. The first transmission filter 121 includes a first substrate 61A, a first low acoustic velocity film 62A, a first piezoelectric layer 63A, and a first circuit portion 642A. The second transmission filter 131 includes a second substrate 61B, a second low acoustic velocity film 62B, a second piezoelectric layer 63B, and a second circuit portion 642B. In addition, in the second transmission filter 131, the main surface 133 on an opposite side from the first transmission filter 121 side is a main surface 612B of the second substrate 61B.

The first electronic component 51c further includes a first resin layer 681. The first resin layer 681 covers the outer peripheral surface of each of the first substrate 61A, the first low acoustic velocity film 62A, the first piezoelectric layer 63A, a conductor 661, a frame 662, the second piezoelectric layer 63B, the second low acoustic velocity film 62B, and the second substrate 61B. The first resin layer 681 further covers the main surface 612B of the second substrate 61B. That is, the first resin layer 681 covers the main surface 133 of the second transmission filter 131 on an opposite side from the first transmission filter 121 side.

The first electronic component 51c further includes a first shield electrode 69. A first shield electrode 69 covers at least a part of the first resin layer 681. Here, the first shield electrode 69 indirectly covers the main surface 133 of the second transmission filter 131. That is, a part of the first resin layer 681 is located between the first shield electrode 69 and the main surface 133 of the second transmission filter 131.

In the radio frequency module 1 according to exemplary embodiment 4, the first resin layer 681 covers at least a part of the first transmission filter 121 and the second transmission filter 131, and the first shield electrode 69 covers at least a part of the first resin layer 681. Thus, it is possible to dissipate the heat generated in the first transmission filter 121 and the second transmission filter 131 through the first shield electrode 69.

In addition, in the radio frequency module 1 according to exemplary embodiment 4, the first shield electrode 69 indirectly covers the main surface 133 of the second transmission filter 131 on the opposite side from the first transmission filter 121 side. Thus, the heat generated in an acoustic wave resonator of the second transmission filter 131 is dissipated from the first shield electrode 69. Thus, the heat dissipation properties of the second transmission filter 131 are improved, and it is possible to reduce the influence of the heat generated in the second transmission filter 131 on the first transmission filter 121.

In addition, in the radio frequency module 1 according to exemplary embodiment 4, a conductor 661 located between the second substrate 61B and the first substrate 61A and a via conductor 671 that penetrates the first substrate 61A in the first direction D1 are connected to a ground electrode 43 of a mounting board 4. Thus, the conductor 661 and the via conductor 671 function as a heat conduction path from the first IDT electrode 641A to the ground electrode 43. Thus, it is possible to reduce the conduction of the heat generated in the first transmission filter 121 to the second transmission filter 131.

In addition, in the radio frequency module 1 according to exemplary embodiment 4, the maximum output power of the power class of a signal passing through the second transmission filter 131 is higher than the maximum output power of the power class of a signal passing through the first transmission filter 121. Thus, the heat generation by the second transmission filter 131 is greater than the heat generation by the first transmission filter 121. As described above, in the radio frequency module 1 according to exemplary embodiment 4, since the heat generation of the second transmission filter 131 is dissipated from the first shield electrode 69, the heat dissipation properties of the second transmission filter 131 are higher than the heat dissipation properties of the first transmission filter 121. Thus, it is possible to reduce the influence of the heat generated in the second transmission filter 131 on the first transmission filter 121 and the second transmission filter 131.

In addition, in the radio frequency module 1 according to exemplary embodiment 4, the second shield electrode 65 is located in the hollow space SP0 and covers at least one of the first IDT electrode 641A that is the first functional electrode, and the second IDT electrode 641B that is the second functional electrode. Thus, it is possible to hinder the transfer of heat between the first transmission filter 121 and the second transmission filter 131. Further, it is possible to improve isolation between the first transmission filter 121 and the second transmission filter 131.

### Exemplary Embodiment 5

A radio frequency module 1a according to exemplary embodiment 5 will be described. Regarding the radio frequency module 1a according to exemplary embodiment 5, the similar configuration to the radio frequency module 1 according to exemplary embodiment 1 is denoted by the same reference numerals, and the description thereof will be omitted.

In the radio frequency module 1a according to exemplary embodiment 5, a transmission signal and a reception signal in the first communication band are time division duplex (TDD) signals. In addition, a transmission signal and a reception signal in the second communication band are TDD signals. The TDD is a radio communication technology in which the same frequency band is allocated to transmission and reception in radio communication, and transmission and reception are switched by the hour. In addition, communication in the first communication band and communication in the second communication band are asynchronous communication. The communication in the first communication band and the communication in the second communication band may be synchronous communication in which a transmission period of the first communication band and a reception period of the second communication band overlap each other in time.

The first communication band is, for example, Band 39 of the 3GPP LTE standard. In addition, the second communication band is, for example, Band 41 of the 3GPP LTE standard. A transmission signal of Band 39 is a signal of the power class 3, and a transmission signal of Band 41 is a signal of the power class 2. The maximum output power of the signal of the power class 2 is larger than the maximum output power of the signal of the power class 3. That is, the maximum output power of the transmission signal in the second communication band is larger than the maximum output power of the transmission signal in the first communication band. The maximum output power is measured by a method defined by, for example, 3GPP.

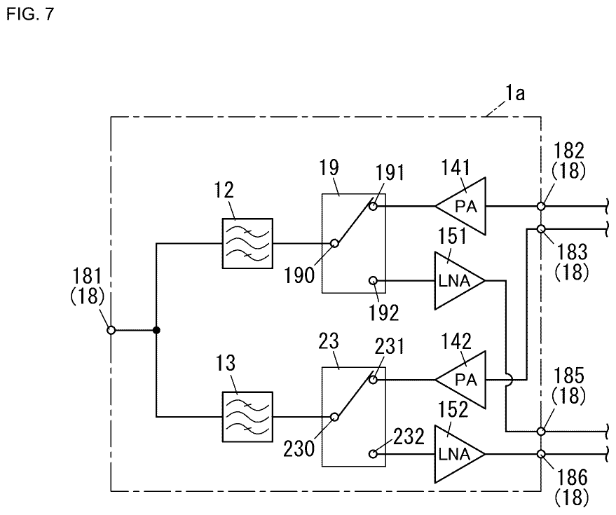

As shown in FIG. 7, the radio frequency module 1a according to exemplary embodiment 5 includes a first filter 12 and a second filter 13 instead of each of the first transmission filter 121 and the first reception filter 122, and the second transmission filter 131 and the second reception filter 132. In addition, the radio frequency module 1a includes a third switch 19 and a fourth switch 23. In addition, the radio frequency module 1a includes an antenna terminal 181, a first input terminal 182, a second input terminal 183, a first output terminal 185, and a second output terminal 186 as a plurality of external connection terminals 18.

The first filter 12 and the second filter 13 are filters that cause signals in frequency bands different from each other to pass therethrough. More specifically, the first filter 12 is a filter that causes a transmission signal and a reception signal in the first communication band to pass through the first filter 12. The second filter 13 is a filter that causes a transmission signal and a reception signal in the second communication band to pass through the second filter 13.

Each of the first filter 12 and the second filter 13 is an acoustic wave filter having one or more acoustic wave resonators, similar to the first transmission filter 121 and the second transmission filter 131. That is, in the present exemplary embodiment, the first filter 12 is a first acoustic wave filter. In addition, in the present exemplary embodiment, the second filter 13 is a second acoustic wave filter. The first filter 12 and the second filter 13 are included in a single first electronic component 51, similar to the first transmission filter 121 and the second transmission filter 131.

The third switch 19 is a switch for switching a path connected to the third switch 19 from among a power amplifier 141 and a low-noise amplifier 151. That is, the third switch 19 is a switch for switching a path to be connected to the first filter 12. The third switch 19 has a common terminal 190 and a plurality of (two in the shown example) selection terminals 191 and 192.

The common terminal 190 is connected to the first filter 12. The selection terminal 191 is connected to the power amplifier 141. In addition, the selection terminal 192 is connected to the low-noise amplifier 151.

The third switch 19 switches the connection between the common terminal 190 and the plurality of selection terminals 191 and 192. The third switch 19 is controlled by, for example, a signal processing circuit 2. The third switch 19 electrically connects the common terminal 190 to any one of the plurality of selection terminals 191 and 192 in accordance with a control signal from the RF signal processing circuit 21 of the signal processing circuit 2.

A fourth switch 23 is a switch for switching a path connected to the fourth switch 23 from among a power amplifier 142 and a low-noise amplifier 152. That is, the fourth switch 23 is a switch for switching a path connected to the fourth switch 23. The fourth switch 23 has a common terminal 230 and a plurality of (two in the shown example) selection terminals 231 and 232.

The common terminal 230 is connected to the second filter 13. The selection terminal 231 is connected to the power amplifier 142. In addition, the selection terminal 232 is connected to the low-noise amplifier 152.

The fourth switch 23 switches the connection between the common terminal 230 and the plurality of selection terminals 231 and 232. The fourth switch 23 is controlled by, for example, the signal processing circuit 2. The fourth switch 23 electrically connects the common terminal 230 to any one of the plurality of selection terminals 231 and 232 in accordance with a control signal from the RF signal processing circuit 21 of the signal processing circuit 2.

The plurality of external connection terminals 18 are terminals for electrical connection to an external circuit (for example, the signal processing circuit 2). The plurality of external connection terminals 18 include an antenna terminal 181, a first input terminal 182, a second input terminal 183, a first output terminal 185, a second output terminal 186, a plurality of control terminals, and a plurality of ground terminals.

The first output terminal 185 is a terminal for outputting a reception signal from the radio frequency module 1 to an external circuit (for example, the signal processing circuit 2). More specifically, the first output terminal 185 outputs a reception signal in the first communication band. In the radio frequency module 1, the first output terminal 185 is connected to the low-noise amplifier 151.

The second output terminal 186 is a terminal for outputting a reception signal from the radio frequency module 1 to the external circuit (for example, the signal processing circuit 2). More specifically, the second output terminal 186 outputs a reception signal in the second communication band. In the radio frequency module 1, the second output terminal 186 is connected to the low-noise amplifier 152.

The radio frequency module 1a includes a first electronic component 51. The first electronic component 51 includes the first filter 12 instead of the first transmission filter 121. In addition, the first electronic component 51 includes the second filter 13 instead of the second transmission filter 131. That is, in the present exemplary embodiment, the first filter 12 is a first acoustic wave filter. In addition, in the present exemplary embodiment, the second filter 13 is a second acoustic wave filter.

The radio frequency module 1a includes a sixth electronic component 56. The sixth electronic component 56 is an IC including the third switch 19 and the fourth switch 23. In addition, in a plan view from the thickness direction D1 of the mounting board 4, the first electronic component 51 and the sixth electronic component overlap each other.

In the radio frequency module 1a according to exemplary embodiment 5, the first resin layer 681 covers at least a part of the first filter 12 and the second filter 13, and the first shield electrode 69 covers at least a part of the first resin layer 681. Thus, it is possible to dissipate the heat generated in the first filter 12 and the second filter 13 through the first shield electrode 69.

In addition, in the radio frequency module 1a according to exemplary embodiment 5, the first shield electrode 69 is in contact with the main surface 133 of the second filter 13 on an opposite side from the first filter 12 side. Thus, the heat generated in an acoustic wave resonator of the second filter 13 is dissipated from the first shield electrode 69. Thus, the heat dissipation properties of the second filter 13 are improved, and it is possible to reduce the influence of the heat generated in the second filter 13 on the first filter 12.

In addition, in the radio frequency module 1a according to exemplary embodiment 5, a conductor 661 located between the second substrate 61B and the first substrate 61A and a via conductor 671 that penetrates the first substrate 61A in the first direction D1 are connected to a ground electrode 43 of a mounting board 4. Thus, the conductor 661 and the via conductor 671 function as a heat conduction path from the first IDT electrode 641A to the ground electrode 43. Thus, it is possible to reduce the conduction of the heat generated in the first filter 12 to the second filter 13.

In addition, in the radio frequency module 1a according to exemplary embodiment 5, the maximum output power of the power class of the transmission signal passing through the second filter 13 is higher than the maximum output power of the power class of the transmission signal passing through the first filter 12. Thus, the heat generation by the second filter 13 is larger than the heat generation by the first filter 12. As described above, since the heat generation of the second filter 13 is dissipated from the first shield electrode 69, the heat dissipation properties of the second filter 13 are higher than the heat dissipation properties of the first filter 12. Thus, it is possible to reduce the influence of the heat generated in the second filter 13 on the first filter 12 and the second filter 13.

In addition, in the radio frequency module 1a according to exemplary embodiment 5, the second shield electrode 65 is located in the hollow space SP0 and covers at least one of the first IDT electrode 641A that is the first functional electrode, and the second IDT electrode 641B that is the second functional electrode. Thus, it is possible to hinder the transfer of heat between the first transmission filter 121 and the second transmission filter 131. Further, it is possible to improve the isolation between the first filter 12 and the second filter 13.

In addition, in the radio frequency module 1a according to exemplary embodiment 5, in a plan view from the thickness direction D1 of the mounting board 4, the first electronic component 51 including the first filter 12 and the second filter 13 overlaps the sixth electronic component including the third switch 19 and the fourth switch 23. Thus, the wiring between the first filter 12 and the third switch 19 is shortened. Similarly, the wiring between the second filter 13 and the fourth switch 23 is shortened. Thus, it is possible to improve the signal quality of a signal passing through the first filter 12 and a signal passing through the second filter 13. That is, in the radio frequency module 1a, the noise resistance of the first filter 12 and the second filter 13 is improved.

### Modification Examples

Modification Examples of exemplary embodiments 1 to 5 will be described below.

Each of the first transmission filter 121, the second transmission filter 131, the first reception filter 122, the second reception filter 132, the first filter 12, and the second filter 13 according to exemplary embodiments 1 and 3 to 5 is not limited to a ladder filter, and may be, for example, a longitudinally coupled resonator type acoustic wave filter.

In addition, each of the first transmission filter 121, the second transmission filter 131, the first reception filter 122, the second reception filter 132, the first filter 12, and the second filter 13 according to exemplary embodiments 1 and 3 to 5 is a surface acoustic wave filter. In addition, each of the first transmission filter 121, the second transmission filter 131, the first reception filter 122, and the second reception filter 132 according to exemplary embodiment 2 is a bulk acoustic wave filter. The acoustic wave filters are not limited to these. For example, the first transmission filter 121 may be a surface acoustic wave filter, and the second transmission filter 131 may be a bulk acoustic wave filter. In addition, the acoustic wave filter may be, for example, an acoustic wave filter using a boundary acoustic wave, a plate wave, or the like.

The first transmission filter 121 and the second transmission filter 131 according to exemplary embodiments 1 to 4 are transmission filters that cause a transmission signal to pass therethrough. However, the present disclosure is not limited to this. For example, at least one of the first transmission filter 121 and the second transmission filter 131 may be a transmission/reception filter that causes a transmission signal and a reception signal to pass therethrough.

In the radio frequency module 1 according to exemplary embodiments 1, 2, 4, and 5, it is assumed that the second shield electrode 65 covers the second IDT electrode 641B or the second upper electrode 643B. However, the present disclosure is not limited to this. For example, the second shield electrode 65 may be configured to cover the first IDT electrode 641A or the first upper electrode 643A.

In the radio frequency module 1 according to exemplary embodiments 1 to 4, the first communication band is Band 1 of the 3GPP LTE standard, and the second communication band is Band 3 of the 3GPP LTE standard. In addition, in the radio frequency module 1 according to exemplary embodiment 5, the first communication band is Band 39 of the 3GPP LTE standard, and the second communication band is Band 41 of the 3GPP LTE standard. However, a combination of the first communication band and the second communication band is not limited to this. The combination of the first communication band and the second communication band is freely made as long as the simultaneous communication is possible. In this case, in a case where the maximum output power of the power class of the signal in the second communication band is larger than the maximum output power of the power class of the signal in the first communication band, the heat generated in the second transmission filter 131 or the second filter 13 is dissipated from the first shield electrode 69 as described above, so that the heat dissipation properties of the radio frequency module 1 are improved.

The maximum output power of the power class of the signal in the first communication band may be larger than the maximum output power of the power class of the signal in the second communication band. For example, the first communication band is Band 41 of the 3GPP LTE standard, and the second communication band is Band 39 of the 3GPP LTE standard. In this case, the heat generated in the first transmission filter 121 or the first filter 12 is dissipated from the mounting board 4, so that the heat dissipation properties of the radio frequency module 1 are improved.

In the radio frequency module 1 according to exemplary embodiments 1 to 4, the first reception filter 122 and the second reception filter 132 are included in the first electronic components 51, 51a, 51b, and 51c, but the present disclosure is not limited to this. For example, each of the first reception filter 122 and the second reception filter 132 may be configured to be included in an electronic component including a single acoustic wave filter.

The radio frequency module 1 according to exemplary embodiments 1 to 5 includes the antenna terminal 181, and the antenna 3 of the communication device 10 is connected to the antenna terminal 181 of the radio frequency module 1. However, the present disclosure is not limited to this. For example, the radio frequency module 1 may include a plurality of antenna terminals, and the communication device 10 may include antennas connected to the plurality of respective antenna terminals. In this case, the radio frequency module 1 includes an antenna switch that selects which transmission path, reception path, or transmission and reception path each of the plurality of antenna terminals is to be connected. The antenna switch may be integrated with the first switch 11 according to exemplary embodiments 1 to 4.

In the present specification, “an element is disposed at a first main surface of a board” includes not only a case where the element is directly mounted on the first main surface of the board but also a case where the element is disposed in a space on the first main surface side between the space on the first main surface side and a space on the second main surface side separated by the board. That is, “the element is disposed at the first main surface of the board” includes a case where the element is mounted on the first main surface of the board with another circuit element, an electrode, or the like interposed therebetween. The element is, for example, the first electronic component 51, but is not limited to the first electronic component 51. The board is, for example, the mounting board 4. In a case where the board is the mounting board 4, the first main surface is the main surface 41, and the second main surface is the main surface 42.

### (Aspects)

The following aspects are disclosed in the present specification.

A radio frequency module (1; 1a) according to a first aspect includes a mounting board (4), a first acoustic wave filter (121; 12), a second acoustic wave filter (131; 13), a first resin layer (681), and a first shield electrode (69). The mounting board (4) has a first main surface (41) and includes a first ground electrode (43). The first acoustic wave filter (121; 12) is disposed at the first main surface (41) of the mounting board (4). The second acoustic wave filter (131; 13) is disposed on the first acoustic wave filter (121; 12). The first resin layer (681) covers at least a part of the first acoustic wave filter (121; 12) and the second acoustic wave filter (131; 13). The first shield electrode (69) covers at least a part of the first resin layer (681). Both the first acoustic wave filter (121; 12) and the second acoustic wave filter (131; 13) are filters that support at least transmission. A first transmission signal passing through the first acoustic wave filter (121; 12) and a second transmission signal passing through the second acoustic wave filter (131; 13) are capable of simultaneous communication. A second main surface (133) of the second acoustic wave filter (131; 13) on an opposite side from a first acoustic wave filter (121; 12) side is in contact with the first shield electrode (69). The first acoustic wave filter (121; 12) includes a first functional electrode (641A; 643A). The first ground electrode (43) of the mounting board (4) is connected to the first functional electrode (641A; 643A) of the first acoustic wave filter (121; 12).

With the radio frequency module (1; 1a) according to the above aspect, there is a heat dissipation path in which heat generated in the first functional electrode (641A; 643A) of the first acoustic wave filter (121; 12) is dissipated to a mounting board (4) side through the first ground electrode (43) of the mounting board (4). In addition, there is a heat dissipation path in which heat generated in the second acoustic wave filter (131; 13) is dissipated to a first shield electrode (69) side through the first shield electrode (69). Thus, it is possible to improve the heat dissipation properties of the first acoustic wave filter (121; 12) and the second acoustic wave filter (131; 13) in the radio frequency module (1; 1a).

A radio frequency module (1; 1a) according to a second aspect in the first aspect further includes conductors (661 and 662). The conductors (661 and 662) connect the first acoustic wave filter (121; 12) and the second acoustic wave filter (131; 13) to each other. The first acoustic wave filter (121; 12) further includes a first support member (61A), a second ground electrode, and a via conductor (671). The first support member (61A) includes two main surfaces (611A and 612A) facing each other. The second ground electrode is connected to the conductors (661 and 662). The via conductor (671) penetrates the first support member (61A) and connects the two main surfaces (611A and 612A) of the first support member (61A) to each other. The second acoustic wave filter (131; 13) further includes a third ground electrode connected to the conductors (661 and 662). The conductors (661 and 662) and the via conductor (671) are connected to the first ground electrodes (43) of the mounting board (4).

With the radio frequency module (1; 1a) according to the above aspect, the thermal conductivity of a heat dissipation path in which heat generated in the first functional electrode (641A; 643A) of the first acoustic wave filter (121; 12) is dissipated to the mounting board (4) side through the first ground electrode (43) of the mounting board (4) is improved. Thus, it is possible to improve the heat dissipation properties of the first acoustic wave filter (121; 12) and the second acoustic wave filter (131; 13) in the radio frequency module (1; 1a).

In a radio frequency module (1; 1a) according to a third aspect, in the first or second aspect, in a plan view from a thickness direction (D1) of the mounting board (4), the first ground electrode (43) of the mounting board (4) and the first functional electrode (641A; 643A) overlap each other.

With the radio frequency module (1; 1a) according to the above aspect, thermal conductivity from the first functional electrode (641A; 643A) of the first acoustic wave filter (121; 12) to the first ground electrode (43) of the mounting board (4) is improved. Thus, it is possible to improve the heat dissipation properties of the first acoustic wave filter (121; 12) and the second acoustic wave filter (131; 13) in the radio frequency module (1; 1a).

A radio frequency module (1; 1a) according to a fourth aspect in any one of the first to third aspects further includes a second resin layer (682). The second resin layer (682) is located between the first acoustic wave filter (121; 12) and the first ground electrode (43) of the mounting board (4).

With the radio frequency module (1; 1a) according to the above aspect, the thermal conductivity of a heat dissipation path from the first functional electrode (641A; 643A) of the first acoustic wave filter (121; 12) to the first ground electrode (43) of the mounting board (4) through the second resin layer (682) is improved. Thus, it is possible to improve the heat dissipation properties of the first acoustic wave filter (121; 12) and the second acoustic wave filter (131; 13) in the radio frequency module (1; 1a).

A radio frequency module (1; 1a) according to a fifth aspect in any one of the first to fourth aspects further includes a second shield electrode (65). The second shield electrode (65) is connected to the first ground electrode (43) of the mounting board (4). The first acoustic wave filter (121; 12) further includes a first support member (61A). The first support member (61A) includes two main surfaces (611A and 612A) facing each other. The second acoustic wave filter (131; 13) further includes a second support member (61B) and a second functional electrode (641B; 643B). The second support member (61B) includes two main surfaces (611B and 612B) facing each other. The first functional electrode (641A; 643A) is provided at the main surface (611A) of the first support member (61A) on a second acoustic wave filter (131; 13) side. The second functional electrode (641B; 643B) is provided at the main surface (611B) of the second support member (61B) on a first acoustic wave filter (121; 12) side. The first functional electrode (641A; 643A) and the second functional electrode (641B; 643B) are located in a hollow space (SP0) and face each other in the thickness direction (D1) of the mounting board (4). The hollow space (SP0) is formed between the first support member (61A) and the second support member (61B) in the thickness direction (D1) of the mounting board (4). The second shield electrode (65) is located in the hollow space (SP0) and covers at least one of the first functional electrode (641A; 643A) or the second functional electrode (641B; 643B).

With the radio frequency module (1; 1a) according to the above aspect, the second shield electrode (65) reduces the heat dissipation from the first acoustic wave filter (121; 12) to the second acoustic wave filter (131; 13) and the heat dissipation from the second acoustic wave filter (131; 13) to the first acoustic wave filter (121; 12). Thus, it is possible to reduce the transfer of heat dissipation between the first acoustic wave filter (121; 12) and the second acoustic wave filter (131; 13) and to improve the heat dissipation properties of the first acoustic wave filter (121; 12) and the second acoustic wave filter (131; 13).

In a radio frequency module (1; 1a) according to a sixth aspect, in any one of the first or third aspects, the first acoustic wave filter (121; 12) further includes a first support member (61A). The first support member (61A) includes two main surfaces (611A and 612A) facing each other. The second acoustic wave filter (131; 13) further includes a second support member (61B) and a second functional electrode (641B; 643B). The second support member (61B) includes two main surfaces (611B and 612B) facing each other. The first functional electrode (641A; 643A) is provided at the main surface (611A) of the first support member (61A) on an opposite side from the second acoustic wave filter (131; 13). The second functional electrode (641B; 643B) is provided at the main surface (611B) of the second support member (61B) on the first acoustic wave filter (121 or 12) side.

With the radio frequency module (1; 1a) according to the above aspect, there is a heat dissipation path in which heat generated in the first functional electrode (641A; 643A) of the first acoustic wave filter (121; 12) is dissipated to the mounting board (4) side. In addition, there is a heat dissipation path in which the heat generated in the second acoustic wave filter (131; 13) is dissipated to the first shield electrode (69) side. Thus, it is possible to improve the heat dissipation properties of the first acoustic wave filter (121; 12) and the second acoustic wave filter (131; 13) in the radio frequency module (1; 1a).

In a radio frequency module (1; 1a) according to a seventh aspect, in any one of the first to sixth aspects, the first acoustic wave filter (121; 12) is a filter for a signal of a first power class. The second acoustic wave filter (131; 13) is a filter for a signal of a second power class. The second power class has a maximum output power higher than the first power class.

With the radio frequency module (1; 1a) according to the aspect, the heat dissipation of the second acoustic wave filter (131; 13) is larger than the heat dissipation of the first acoustic wave filter (121; 12). Thus, since the heat dissipation to the first shield electrode (69) side is larger than the heat dissipation to the mounting board (4) side, it is possible to suppress an increase in the temperature of the radio frequency module (1; 1a).

In a radio frequency module (1; 1a) according to an eighth aspect in any one of the first to seventh aspects, the first acoustic wave filter (121; 12) is a filter that causes a transmission signal of Band 39 of a 3GPP LTE standard to pass, and the second acoustic wave filter (131; 13) is a filter that causes a transmission signal of Band 41 of the 3GPP LTE standard to pass.

With the radio frequency module (1; 1a) according to the aspect, it is possible to perform simultaneous communication using Band 39 and Band 41 of the 3GPP LTE standard.

A communication device (10) according to a ninth aspect includes the radio frequency module (1; 1a) according to any one of the first to eighth aspects, and a signal processing circuit (2). The signal processing circuit (2) is connected to the radio frequency module (1; 1a).

With the communication device (10) according to the aspect, there is a heat dissipation path in which the heat generated in the first functional electrode (641A; 643A) of the first acoustic wave filter (121; 12) is dissipated to the mounting board (4) side through the first ground electrode (43) of the mounting board (4). In addition, there is a heat dissipation path in which heat generated in the second acoustic wave filter (131; 13) is dissipated to a first shield electrode (69) side through the first shield electrode (69). Thus, it is possible to improve the heat dissipation properties of the first acoustic wave filter (121; 12) and the second acoustic wave filter (131; 13) in the radio frequency module (1; 1a).

### REFERENCE SIGNS LIST

1, 1a RADIO FREQUENCY MODULE
10 COMMUNICATION DEVICE
11 FIRST SWITCH
110 COMMON TERMINAL
111 SELECTION TERMINAL
112 SELECTION TERMINAL
121 FIRST TRANSMISSION FILTER (FIRST ACOUSTIC WAVE FILTER)
122 FIRST RECEPTION FILTER
12 FIRST FILTER (FIRST ACOUSTIC WAVE FILTER)
131 SECOND TRANSMISSION FILTER (SECOND ACOUSTIC WAVE FILTER)
132 SECOND RECEPTION FILTER
13 SECOND FILTER (SECOND ACOUSTIC WAVE FILTER)
133 MAIN SURFACE (SECOND MAIN SURFACE)
141 POWER AMPLIFIER
142 POWER AMPLIFIER
151 LOW-NOISE AMPLIFIER
152 LOW-NOISE AMPLIFIER
16 SECOND SWITCH
160 COMMON TERMINAL
161 SELECTION TERMINAL
162 SELECTION TERMINAL
171 MATCHING CIRCUIT
172 MATCHING CIRCUIT
173 MATCHING CIRCUIT
174 MATCHING CIRCUIT
175 MATCHING CIRCUIT
176 MATCHING CIRCUIT
18 EXTERNAL CONNECTION TERMINAL
181 ANTENNA TERMINAL
182 FIRST INPUT TERMINAL
183 SECOND INPUT TERMINAL
184 OUTPUT TERMINAL
185 FIRST OUTPUT TERMINAL
186 SECOND OUTPUT TERMINAL
19 THIRD SWITCH
190 COMMON TERMINAL
191 SELECTION TERMINAL
192 SELECTION TERMINAL
23 FOURTH SWITCH
230 COMMON TERMINAL
231 SELECTION TERMINAL
232 SELECTION TERMINAL
2 SIGNAL PROCESSING CIRCUIT
21 RF SIGNAL PROCESSING CIRCUIT
22 BASEBAND SIGNAL PROCESSING CIRCUIT
3 ANTENNA
4 MOUNTING BOARD
41 MAIN SURFACE (FIRST FRONT SURFACE)
42 MAIN SURFACE
43 GROUND ELECTRODE (FIRST GROUND ELECTRODE)
51, 51a, 51b, 51c FIRST ELECTRONIC COMPONENT
52 SECOND ELECTRONIC COMPONENT
53 THIRD ELECTRONIC COMPONENT
54 FOURTH ELECTRONIC COMPONENT
55 FIFTH ELECTRONIC COMPONENT
56 SIXTH ELECTRONIC COMPONENT
61A FIRST SUBSTRATE (FIRST SUPPORT MEMBER)
611A MAIN SURFACE
612A MAIN SURFACE
61B SECOND SUBSTRATE (SECOND SUPPORT MEMBER)
611B MAIN SURFACE
612B MAIN SURFACE
62A FIRST LOW ACOUSTIC VELOCITY FILM
62B SECOND LOW ACOUSTIC VELOCITY FILM
63A FIRST PIEZOELECTRIC LAYER
63B SECOND PIEZOELECTRIC LAYER
641A FIRST IDT ELECTRODE (FIRST FUNCTIONAL ELECTRODE)
641B SECOND IDT ELECTRODE (SECOND FUNCTIONAL ELECTRODE)
642A FIRST CIRCUIT PORTION
642B SECOND CIRCUIT PORTION
643A FIRST UPPER ELECTRODE
643B SECOND UPPER ELECTRODE
644A FIRST PIEZOELECTRIC FILM
644B SECOND PIEZOELECTRIC FILM
645A FIRST LOWER ELECTRODE
645B SECOND LOWER ELECTRODE
646A CAVITY
646B CAVITY
65 SECOND SHIELD ELECTRODE
661 CONDUCTOR
662 FRAME (CONDUCTOR)
671 VIA CONDUCTOR
672 BUMP
673 CONDUCTOR
674 BUMP
681 FIRST RESIN LAYER
682 SECOND RESIN LAYER
69 FIRST SHIELD ELECTRODE
D1 FIRST DIRECTION
SP0 HOLLOW SPACE
SP1 FIRST SPACE
SP2 SECOND SPACE

1. A radio frequency module comprising:
a mounting board that has a first main surface and includes a first ground electrode;
a first acoustic wave filter including a first support that is disposed at the first main surface of the mounting board;
a second acoustic wave filter including a second support that is disposed on the first acoustic wave filter; and
a first shield electrode that covers at least a part of the second acoustic wave filter,
wherein,
the first acoustic wave filter and the second acoustic wave filter are configured to pass a first transmission signal passing and a second transmission signal to perform simultaneous communication,
a second main surface of the second acoustic wave filter on an opposite side from a first acoustic wave filter side is in contact with the first shield electrode,
the first acoustic wave filter includes a first functional electrode, and
the first ground electrode of the mounting board is connected to the first functional electrode of the first acoustic wave filter.

2. The radio frequency module according to claim 1, further comprising:
a first circuit portion that is next to the first functional electrode,
wherein the first circuit portion includes a second ground electrode which is connected to the first ground electrode.

3. The radio frequency module according to claim 1, wherein, in a plan view from a thickness direction of the mounting board, the first ground electrode of the mounting board overlaps the first functional electrode.

4. The radio frequency module according to claim 1, further comprising:
a first resin layer that covers at least a part of the first acoustic wave filter and the second acoustic wave filter;
a second resin layer that is located between the first acoustic wave filter and the first ground electrode of the mounting board, wherein at least a part of the first resin layer is located between the first shield electrode and the second acoustic wave filter.

5. The radio frequency module according to claim 1, further comprising:
a second shield electrode that is connected to the first ground electrode of the mounting board,
wherein
the second acoustic wave filter further includes a second functional electrode,
the first functional electrode is provided at a main surface of the first support on a second acoustic wave filter side,
the second functional electrode is provided at a main surface of the second support on the first acoustic wave filter side,
the first functional electrode and the second functional electrode are located in a hollow space formed between the first support and the second support in a thickness direction of the mounting board, and face each other in the thickness direction of the mounting board, and
the second shield electrode is located in the hollow space and covers at least one of the first functional electrode and the second functional electrode.

6. The radio frequency module according to claim 1,
wherein
the second acoustic wave filter further includes a second functional electrode,
the first functional electrode is provided at a main surface of the first support on an opposite side from the second acoustic wave filter, and
the second functional electrode is provided at a main surface of the second support on the first acoustic wave filter side.

7. The radio frequency module according to claim 1,
wherein the first acoustic wave filter is a filter for a signal of a first power class, and
the second acoustic wave filter is a filter for a signal of a second power class having a maximum output power higher than the first power class.

8. The radio frequency module according to claim 1, wherein the first acoustic wave filter is a filter that causes a transmission signal of Band 39 of a 3GPP LTE standard to pass, and the second acoustic wave filter is a filter that causes a transmission signal of Band 41 of the 3GPP LTE standard to pass.

9. The radio frequency module according to claim 5, wherein the first functional electrode the second functional electrode are interdigital transducer (IDT) electrode.

10. The radio frequency module according to claim 9, further comprising:
a first piezoelectric layer is located between the first functional electrode and the first support, and
a second piezoelectric layer is located between the second functional electrode and the second support.

11. The radio frequency module according to claim 10, further comprising:
a first low acoustic velocity film is located between the first piezoelectric layer and the first support, and
a second low acoustic velocity film is located between the second piezo electric layer and the second support.

12. The radio frequency module according to claim 5, wherein the first functional electrode the second functional electrode are Bulk Acoustic Wave (BAW) filter.

13. The radio frequency module according to claim 1, wherein both the first acoustic wave filter and the second acoustic wave filter are filters that support transmission or reception.

14. The radio frequency module according to claim 1, wherein either the first acoustic wave filter or the second acoustic wave filter is a filter that supports transmission, and the other is a filter that supports reception.

15. A communication device comprising:
a radio frequency module; and
a signal processing circuit that is connected to the radio frequency module, wherein the radio frequency module includes:
a mounting board that has a first main surface and includes a first ground electrode;
a first acoustic wave filter including a first support that is disposed at the first main surface of the mounting board;
a second acoustic wave filter including a second support that is disposed on the first acoustic wave filter; and
a first shield electrode that covers at least a part of the second acoustic wave.

16. The communication device according to claim 15 further comprising:
an antenna which is connected to the radio frequency module.

17. The communication device according to claim 15, wherein the radio frequency module further including a low noise amplifier and a power amplifier.

18. The communication device according to claim 15, wherein the radio frequency module further including a matching circuit.

19. The communication device according to claim 15 further comprising:
a radio frequency integrated circuit and a baseband integrated circuit.

20. The radio frequency module according to claim 1, wherein the first acoustic wave filter and the second acoustic wave filter are separated by a gap.
